(19) United States
(12) Patent Application Publication
(10) Pub. No.: US 2026/0271488 A1
(43) Pub. Date: Sep. 10, 2026

(54) LIGHT-EMITTING ELEMENT, AND DISPLAY DEVICE

(71) Applicant: Sharp Display Technology Corporation, Kameyama City, Mie (JP)

(72) Inventor: Kazuki MARUHASHI, Saki City, Osaka (JP)

(21) Appl. No.: 18/869,463

(22) PCT Filed: Jul. 19, 2022
(86) PCT No.: PCT/JP2022/028004

§ 371 Date: Nov. 26, 2024

(51) Int. Cl. H10K 50/115; B82Y 20/00; B82Y 40/00; C01G 53/40; H10K 77/10; H10K 101/40

(52) U.S. Cl. CPC H10K 50/115; C01G 53/40; B82Y 20/00; B82Y 40/00; C01P 2002/60; C01P 2002/74; C01P 2006/40; C01P 2006/60; H10K 77/111; H10K 2101/40

(57) ABSTRACT

A light-emitting element includes: an anode; a cathode; a quantum-dots layer positioned between the anode and the cathode, and including a quantum dot; and a metal oxide layer positioned between the anode and the quantum-dots layer, and containing a nickel element and at least one non-nickel metal element selected from Li, Na, K, Rb, Cs, Fe, Co, Cu, and Ag at a composition ratio of (1-x):x, where 0.05≤x≤0.5 is satisfied.

### TECHNICAL FIELD

The present disclosure relates to a light-emitting element, a display device, and a method for manufacturing a light-emitting element.

### BACKGROUND ART

Patent Literature 1 discloses a light-emitting element that includes, but not limited to, a hole injection layer containing nickel oxide (NiOₓ).

### CITATION LIST

### Patent Literature

Patent Literature 1: Japanese Unexamined Patent Application Publication No. 2012-533156

### SUMMARY

### Technical Field

A problem in the light-emitting element described in Patent Literature 1 is a high driving voltage.

### Solution to Problem

A light-emitting element according to one aspect of the present disclosure includes the following: an anode; a cathode; a quantum-dots layer positioned between the anode and the cathode, and including a quantum dot; and a metal oxide layer positioned between the anode and the quantum-dots layer, and containing a nickel element and at least one non-nickel metal element selected from Li, Na, K, Rb, Cs, Fe, Co, Cu, and Ag at a composition ratio of (1-x):x, where 0.05≤x≤0.5 is satisfied.

### Advantageous Effect of Disclosure

The aspect of the present disclosure can achieve a light-emitting element with a low driving voltage.

### BRIEF DESCRIPTION OF DRAWINGS

FIG. 1 is a cross-sectional view of the schematic configuration of a light-emitting element according to a first embodiment of the present disclosure.

FIG. 2 is a schematic diagram illustrating a method for manufacturing the light-emitting element according to the first embodiment of the present disclosure.

FIG. 3 is graphs showing the relationship of luminance versus driving voltage in a light-emitting element (containing 0% of Cu), a light-emitting element (containing 15% of Cu), and a light-emitting element (containing 30% of Cu).

FIG. 4 is graphs showing the relationship of current density versus driving voltage in the light-emitting element (containing 0% of Cu), the light-emitting element (containing 15% of Cu), and the light-emitting element (containing 30% of Cu).

FIG. 5 is graphs showing the relationship of EQE versus luminance in the light-emitting element (containing 0% of Cu), the light-emitting element (containing 15% of Cu), and the light-emitting element (containing 30% of Cu).

FIG. 6 is graphs showing the relationship of EQE versus current density in the light-emitting element (containing 0% of Cu), the light-emitting element (containing 15% of Cu), and the light-emitting element (containing 30% of Cu).

FIG. 7 is graphs showing the relationship of EQE versus driving voltage in the light-emitting element (containing 0% of Cu), the light-emitting element (containing 15% of Cu), and the light-emitting element (containing 30% of Cu).

FIG. 8 is a table showing EQE at a current density of 10 mA/cm² in the light-emitting element (containing 0% of Cu), the light-emitting element (containing 15% of Cu), and the light-emitting element (containing 30% of Cu).

FIG. 9 is graphs showing the relationship of light transmittance versus light wavelength in a glass substrate, a metal oxide film (containing 5% of Cu), a metal oxide film (containing 30% of Cu), and a metal oxide film (containing 50% of Cu).

FIG. 10 is a cross-sectional view of the schematic configuration of a light-emitting element according to a second embodiment of the present disclosure.

FIG. 11 illustrates hole injection from a metal oxide layer into a quantum dot.

FIG. 12 is a cross-sectional view of the schematic configuration of a display device according to a third embodiment of the present disclosure.

### DESCRIPTION OF EMBODIMENTS

Embodiments of the present disclosure will be described. For convenience in description, components having the same functions as those of earlier described components will be denoted by the same signs, and their description will not be repeated in some cases.

### First Embodiment

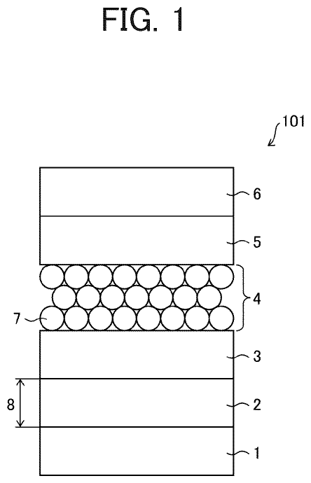

FIG. 1 is a cross-sectional view of the schematic configuration of a light-emitting element 101 according to a first embodiment of the present disclosure. The light-emitting element 101 includes an anode 1, a metal oxide layer 2, an organic carrier transport layer 3, a quantum-dots layer 4, an electron transport layer 5, and a cathode 6. The anode 1, the metal oxide layer 2, the organic carrier transport layer 3, the quantum-dots layer 4, the electron transport layer 5, and the cathode 6 are stacked on a substrate (not shown) in the stated order. The light-emitting element 101 is a so-called conventional-structure light-emitting element.

The light-emitting element 101 is a quantum-dot light-emitting diode (QLED) element. The light-emitting element 101 is an element in which the quantum-dots layer 4 emits light by current flowing between the anode 1 and the cathode 6. In the light-emitting element 101, the metal oxide layer 2 functions as a hole injection layer, and the organic carrier transport layer 3 functions as a hole transport layer.

The quantum-dots layer 4 is positioned between the anode 1 and the cathode 6 and includes quantum dots 7. The quantum-dots layer 4 is a light-emitting layer. The quantum dots 7 may be non-cadmium quantum dots.

Each quantum dot 7 is a dot whose maximum width measures 100 nm or less. The quantum dot 7 has any shape satisfying this maximum width; the shape is not limited to a spherical tridimensional shape (circular cross-section shape). For instance, each quantum dot may have a polygonal cross-section shape, a bar-shaped tridimensional shape, a branch-shaped tridimensional shape, a tridimensional shape having surface asperities, or a combination of them.

The quantum dot 7 may be typically composed of a semiconductor. The semiconductor may have a constant band gap. The semiconductor needs to be a material capable of emitting light.

Moreover, at least the following materials may be contained. The semiconductor may emit red, green, and blue light individually. The semiconductor contains, for example, at least one selected from the group consisting of a Group IV single element, a Group IV compound, a Group II-VI compound, a Group III-V compound, a chalcogenide, and a perovskite compound. It is noted that a Group IV single element is a single element consisting of a Group IV element, and that a Group IV compound is a compound containing a Group IV element. It is also noted that a Group II-VI compound is a compound containing a Group II element and a Group VI element, and that a Group III-V compound is a compound containing a Group III element and a Group V element. It is also noted that Group II elements can include group 2 elements and group 12 elements, that Group III elements can include group 3 elements and group 13 elements, that Group IV elements can include group 4 elements and group 14 elements, that Group V element can include group 5 elements and group 15 elements, and that Group VI elements can include group 6 elements and group 16 elements.

The Group IV compound contains at least one selected from the group consisting of C, Si, and Ge for instance.

The Group II-VI compound contains at least one selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe for instance.

The Group III-V compound contains at least one selected from the group consisting of GaP, GaAs, GaSb, InN, InP, InAs, and InSb for instance.

The chalcogenide is a compound containing a group 16 element and contains, for example, CdS or CdSe. The chalcogenide may contain a mixed crystal of these materials.

The perovskite compound has a composition represented by, for example, the general formula CsPbX₃, CsSnX₃, CH₃NH₃PbX₃, or CH₃NH₃SnX₃. The constituent element X contains at least one selected from the group consisting of Cl, Br, and I for instance.

Here, the notation of element group numbers using Roman numerals is notation based on the former IUPAC system or the former CAS system, and the notation of element group numbers using Arabic numerals is notation based on the current IUPAC system.

The metal oxide layer 2 is positioned between the anode 1 and the quantum-dots layer 4. The metal oxide layer 2 contains nickel oxide. The metal oxide layer 2 contains a nickel element and a non-nickel metal element. The non-nickel metal element is one or more selected from Li, Na, K, Rb, Cs, Fe, Co, Cu, and Ag. These non-nickel metal elements increase holes within the metal oxide layer 2 by at least one of a mechanism for replacing bivalent nickel sites with univalent positive ions, and a mechanism for increasing metal-deficient sites within the metal oxide layer 2. Thus, these non-nickel metal elements improve the hole transport ability and hole injection ability of the metal oxide layer 2.

The composition ratio between the nickel element and non-nickel metal element contained in the metal oxide layer 2 is expressed as (1-x):x. At this time, 0.05≤x≤0.5 is satisfied. The metal oxide layer 2 is MₓNi₍₁₋ₓ₎O_{y} (M is a generic name for non-nickel metal elements), which can be then interpreted as satisfying 0.05≤x≤0.5.

Each of the composition of the nickel element and the composition of the non-nickel metal element can be obtained through, for example, energy-dispersive X-ray analysis (EDX) or, when not specified through EDX, through elemental analysis by X-ray photoelectron spectroscopy (XPS). Subjecting the cross-section of the light-emitting element 101 to this elemental analysis can facilitate obtaining each of the composition of the non-nickel metal element and the composition of the non-nickel metal element.

The light-emitting element 101 has a small energy level difference between the organic carrier transport layer 3 and the quantum-dots layer 4 including the non-cadmium quantum dots 7. Hence, even if including the metal oxide layer 2 doped with a high concentration (e.g., 0.1≤x) of a non-nickel metal element, the light-emitting element 101 is less likely to have holes accumulated at the interface between the organic carrier transport layer 3 and quantum-dots layer 4 and is thus less likely to cause nonradiative recombination, thereby achieving high EQE. This can achieve the light-emitting element 101 with a low driving voltage, and with the metal oxide layer 2 doped with a high concentration of a non-nickel metal element. Further, the non-cadmium quantum dots 7, which impose a less environmental load and do less harm to health than cadmium-containing quantum dots, can be suitably used for light-emitting elements.

The non-cadmium quantum dots 7 are defined as follows: In a cross-sectional observation of the quantum-dots layer 4, at least one of the quantum dots undergoes elemental analysis across its widest part, and in response to no cadmium detection or a detection intensity that is equal to or lower than a noise level, this quantum dot(s) within the quantum-dots layer 4 is determined to be a non-cadmium quantum-dot(s). An apparatus for this needs to be one for determining the composition of a nickel element.

The metal oxide layer 2 preferably contains nickel oxide with low crystallinity. This provides a low rate of hole activation in the metal oxide layer 2 doped with a high concentration of the non-nickel metal element, thereby achieving actions and effects listed in (A) and (B) below.

(A) Doping the foregoing nickel oxide with a large volume of the non-nickel metal element can achieve the light-emitting element 101 with high EQE and a low driving voltage.

(B) Even if more or less variations in volume of doping the nickel oxide with the non-nickel metal element are found between the light-emitting elements 101, the electrical properties of the light-emitting elements 101 do not change greatly. This is favorable for manufacturing the light-emitting elements 101.

At least a part of the metal oxide layer 2 may have a structure of an amorphous metal oxide. At least a part of the metal oxide layer 2 may have a structure of polycrystals, and the average crystal particle diameter of the polycrystals may be less than 25 percent of a thickness 8 of the metal oxide layer 2. The particle diameters may be measured through cross-section analysis using a transmission electron microscope (TEM) or a scanning electron microscope (SEM). At this time, when the crystal particles are not spherical, the particle diameters can be the diameters of such crystal particles undergone equivalent transformation into spheres. Further, when the particle diameters exhibit distribution, in the particle diameter distribution of all crystal particles (e.g., 10 to 100 crystal particles) in the observation field of view for instance, a particle diameter D50 at which the cumulative number of them reaches 50% for instance can be regarded as the particle diameter of the whole. Further, the crystal particle diameters may be measured through small-angle X-ray scattering. It is noted that an analysis result using a TEM has higher priority than an analysis result using a SEM, and a cross-section analysis result has higher priority than an analysis result through small-angle X-ray scattering.

The light-emitting element 101 may be configured such that the peak of the nickel oxide (200) (2θ=43.25°) is not observed in the X-ray diffraction pattern of the light-emitting element 101. The light-emitting element 101 may be configured such that the peak of the nickel oxide (200) is one-tenth or less as small as the highest peak in the X-ray diffraction pattern of the light-emitting element 101. This can achieve the metal oxide layer 2 containing metal oxide with low nickel-oxide crystallinity, thereby achieving an effect similar to that achieved by an amorphous metal oxide layer. The metal oxide layer 2 may be a film formed by firing a precursor of metal salt, such as metal acetate or metal nitrate, at a firing temperature that is low (e.g., 245° C.) as a temperature for forming oxides.

The metal oxide layer 2 may have a light transmittance of 65% or more at a wavelength of 400 to 700 nm inclusive. Accordingly, the metal oxide layer 2 absorbs a small amount of light, thereby enhancing light extraction efficiency, thus achieving the light-emitting element 101 with high EQE.

The non-nickel metal element contained in the metal oxide layer 2 is typically Cu among the foregoing listed elements.

The metal oxide layer 2 may include a plurality of metal oxide crystals, and the plurality of metal oxide crystals may have an average particle diameter of 30 nm or less. Their particle diameters may be measured through cross-section analysis with a TEM or a SEM, or through small-angle X-ray scattering; in addition, as earlier described, an analysis result using a TEM has the highest priority.

An inequality 0.15≤x may be satisfied. This reduces driving voltage in the light-emitting element 101 prominently.

An inequality 0.25≤x may be satisfied. This reduces driving voltage in the light-emitting element 101 more prominently. The larger the value x is, the lower the transmittance of the metal oxide layer 2 can be. However, in 0.25≤x, an EQE increase of the light-emitting element 101 resulting from a carrier balance improvement thanks to an increase in the amount of hole injection into the quantum-dots layer 4 is greater than an EQE decrease of the light-emitting element 101 resulting from a transmittance reduction of the metal oxide layer 2. As such, the inequality 0.25≤x can achieve the light-emitting element 101 with sufficiently high EQE.

Each non-cadmium quantum dot 7 may contain at least one of Si, Ge, SiGe, AlSb, GaP, GaAs, GaSb, InP, InAs, InSb, ZnSiAs₂, ZnSiSb₂, ZnGeP₂, ZnGeAs₂, ZnGeSb₂, ZnSnP₂, ZnSnAs₂, ZnSnSb₂, CuGaS₂, CuGaSe₂, CuGaTe₂, CuInS₂, CuInSe₂, CuInTe₂, AgAlS₂, AgAlSe₂, AgAlTe₂, AgGaS₂, AgGaSe₂, AgGaTe₂, AgInS₂, AgInSe₂, and AgInTe₂. These materials for the non-cadmium quantum dots 7 can achieve the non-cadmium quantum dots 7 in each of which the difference between the energy level of the highest occupied molecular orbital and a vacuum level is 6 eV or less.

The energy level of the lowest unoccupied molecular orbital (LUMO) and the energy level of the highest occupied molecular orbital (HOMO) hereinafter stand at negative values (in the unit eV) with a vacuum level as a criterion (zero). In the following description, a conduction band minimum (CBM) can be substituted for LUMO, and a valence band maximum (VBM) can be substituted for HOMO.

Further, a smaller energy level (a smaller value of energy level) means that the energy level is more distant from a vacuum level, that is, the level is deeper. Further, a larger energy level (a larger value of energy level) means that the energy level is closer to the vacuum level, that is, the level is shallower.

Further, the difference between the energy level of the highest occupied molecular orbital and the vacuum level (the magnitude of the difference, i.e., the absolute value of the difference) can be referred to as ionization energy in other words, and the difference between the energy level of the lowest unoccupied molecular orbital and the vacuum level can be referred to as electron affinity in other words.

Each quantum dot 7 is not limited to a non-cadmium quantum dot; the difference between the energy level of the highest occupied molecular orbital of the quantum dot 7 and the vacuum level may be 6 eV or less.

Hole injection into the quantum dot 7 is easy at a difference of 6 eV or less between the energy level of the highest occupied molecular orbital of the quantum dot 7 and the vacuum level. The light-emitting element 101 is less likely to exhibit hole excess because it has a larger ratio of electron mobility within the light-emitting layer divided by hole mobility within the light-emitting layer (or a difference obtained by subtracting the hole mobility within the light-emitting layer from the electron mobility within the light-emitting layer) than a typical organic light-emitting diode (OLED) element. They constitute a ground for the fact that satisfying the condition 0.05≤x is useful in the light-emitting element 101. That is, since QLED elements exhibit electron excess in many cases, the further hole injection is enhanced, the further carrier balance improves, thus enhancing EQE.

The organic carrier transport layer 3 is positioned between the quantum-dots layer 4 and the metal oxide layer 2. The organic carrier transport layer 3 may be any of poly-TPD, TFB, PVK, TAPC, TCTA, α-NPD, and TPD. The difference between the energy level of the highest occupied molecular orbital of the organic carrier transport layer 3 and a vacuum level may be larger than the difference between the energy level of the highest occupied molecular orbital of the metal oxide layer 2 and a vacuum level. The difference between the energy level of the highest occupied molecular orbital of the organic carrier transport layer 3 and the vacuum level may be 5.1 eV or more. The foregoing facilitates a configuration in which the energy level of the highest occupied molecular orbital of the organic carrier transport layer 3 is between the energy level of the highest occupied molecular orbital of the metal oxide layer 2 and the energy level of the highest occupied molecular orbital of the quantum dot 7. This configuration facilitates hole injection into the quantum dot 7.

It is noted that poly-TPD, TFB, PVK, TAPC, TCTA, α-NPD, and TPD are each abbreviations of the following.
Poly-TPD: Poly-4-butyl-N,N-diphenylaniline
TFB: Poly[(9,9-dioctylfluorenyl-2,7-diyl)-co-(4,4′-(N-(4-sec-butylphenyl))diphenylamine)]
PVK: Poly(9-vinylcarbazole)
TAPC: 4,4′-(1,1-Cyclohexanediyl)bis[N,N-bis(4-methylphenyl)aniline]
TCTA: 4,4′,4″-Tris(carbazol-9-yl)triphenylamine
α-NPD: N,N′-Di-1-naphthyl-N,N′-diphenylbenzidine
TPD: N,N′-Bis(3-methylphenyl)-N,N′-diphenylbenzidine

The metal oxide layer 2 may be 3 nm or less in surface roughness Rz. This can prevent current from concentrating locally, thus reducing ineffective current that is not injected into the quantum dots, thereby achieving the light-emitting element 101 with high EQE. In addition, local deterioration caused by such local current concentration is prevented, thereby achieving the light-emitting element 101 with high reliability. The surface roughness Rz of the metal oxide layer 2 is determined by the sum of the maximum peak height and maximum valley depth of the surface of the metal oxide layer 2. The surface roughness Rz may be determined through, for instance, cross-section analysis using a TEM or a SEM.

The metal oxide layer 2 may contain no carbon element or contains a carbon element whose mole ratio to a metal element is 0.3 or less. The metal element includes a nickel element and a non-nickel metal element. In other words, the metal oxide layer 2 may contain no ligand, or a few ligands. This can increase the hole mobility and hole injection ability of the metal oxide layer 2, thereby achieving the light-emitting element 101 with low driving voltage.

The light-emitting element 101 may include a self-assembled monolayer between the metal oxide layer 2 and the organic carrier transport layer 3, as necessary.

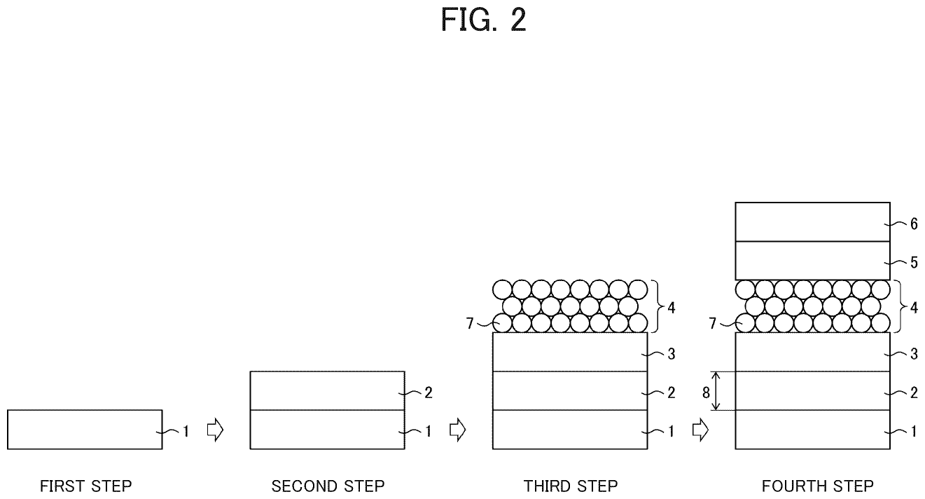

FIG. 2 schematically illustrates a method for manufacturing the light-emitting element 101. The method for manufacturing the light-emitting element 101 includes first to fourth steps.

The first step is a step of forming the anode 1.

The second step is a step of firing, at 350 degrees or less, a coating film including a liquid containing c×(1−a) mol of a nickel element, and a liquid containing c×a mol of at least one non-nickel metal element selected from Li, Na, K, Rb, Cs, Fe, Co, Cu, and Ag, where a and c denote positive numbers, and where 0.05≤a≤0.5 is satisfied. The metal oxide layer 2 is formed in the second step.

The method for manufacturing the light-emitting element 101 includes a step of forming the organic carrier transport layer 3 between the second and third steps.

The third step is a step of forming the quantum-dots layer 4 including the non-cadmium quantum dots 7.

The method for manufacturing the light-emitting element 101 includes a step of forming the electron transport layer 5 between the third and fourth steps.

The fourth step is a step of forming the cathode 6.

Since the light-emitting element 101 has a conventional structure, the quantum-dots layer 4 is positioned higher than the metal oxide layer 2. That is, the quantum-dots layer 4 is spatially more distant from the substrate than the metal oxide layer 2. The quantum-dots layer 4 does not thus receive heat generated during the firing for forming the metal oxide layer 2 in the second step, thereby preventing the quantum dots 7 from deterioration.

Since the light-emitting element 101 has a conventional structure, the metal oxide layer 2 is formed higher than the anode 1. The anode 1 may contain indium tin oxide (ITO). ITO reduces its conductivity considerably when exposed to a high temperature of 300 degrees or more.

In the present disclosure, the firing temperature for forming the metal oxide layer 2 is set at about 300 degrees or less. This setting is suitable for forming the metal oxide layer 2 containing nickel oxide with low crystallinity. The anode 1 may have a monolayer structure including a single ITO layer, or a multilayer structure including a single ITO layer and another layer.

The conductivity of the metal oxide layer 2 may be larger than the conductivity of the electron transport layer 5. In this case, hole injection is promoted further than electron injection, and carrier balance is adjusted, so that EQE is easily improved.

### EXAMPLES

A light-emitting element (containing 0% of Cu), a light-emitting element (containing 15% of Cu), and a light-emitting element (containing 30% of Cu) were produced, and their electrical properties were compared.

Here, 1 mmol of nickel acetate tetrahydrate (Ni(CH₃COOH)₂·4H₂O) and 5 mL of ethanol were put into a vial container and were stirred well for 30 minutes to prepare a precursor solution (containing 0% of Cu).

In addition, 0.85 mmol of nickel acetate tetrahydrate (Ni(CH₃COOH)₂·4H₂O), 0.15 mmol of copper acetate monohydrate (Cu(CH₃COOH)₂·H₂O), and 5 mL of ethanol were put into a vial container and were stirred well for 30 minutes to prepare a precursor solution (containing 15% of Cu).

In addition, 0.7 mmol of nickel acetate tetrahydrate (Ni(CH₃COOH)₂·4H₂O), 0.3 mmol of copper acetate monohydrate (Cu(CH₃COOH)₂·H₂O), and 5 mL of ethanol were put into a vial container and were stirred well for 30 minutes to prepare a precursor solution (containing 30% of Cu).

### Production of Light-Emitting Element (Containing 0% of Cu)

A 30-nm thick ITO film was formed onto a glass substrate through sputtering to form an anode (corresponding to the anode 1). This corresponds to the first step.

The precursor solution (containing 0% of Cu) underwent spin-coating application to the anode under the atmosphere, followed by firing at 275 degrees for 1 hour to form a 45-nm thick NiO_{y} layer (corresponding to the metal oxide layer 2). This corresponds to the second step.

A solution with [2-(3,6-Dimethoxy-9H-carbazol-9-yl)ethyl]phosphonic acid (MeO-2PACz) dispersed in an ethanol solvent underwent spin-coating application to a NiO_{y} layer under a N2 atmosphere, followed by solvent volatilization through firing to form a self-assembled monolayer.

A solution with poly-TPD dispersed in a chlorobenzene solvent underwent spin-coating application to the self-assembled monolayer under a N2 atmosphere, followed by solvent volatilization through firing to form a 30-nm thick poly-TPD film (corresponding to the organic carrier transport layer 3).

A solution with InP quantum-dot phosphor particles dispersed in an octane solvent underwent spin-coating application to the poly-TPD film under a N2 atmosphere to form a 20-nm thick light-emitting layer (corresponding to the quantum-dots layer 4). This corresponds to the third step.

A solution with ZnO nanoparticles dispersed in an ethanol solvent underwent spin-coating application to the light-emitting layer under a N2 atmosphere to form a 55-nm thick ZnO-nanoparticles film (corresponding to the electron transport layer 5).

A 65-nm thick Ag film was formed onto the ZnO-nanoparticles film through vacuum evaporation to form a cathode (corresponding to the cathode 6). This corresponds to the fourth step.

The glass substrate and the members formed on the glass substrate were sealed with a sealant under a N2 atmosphere.

The ZnO nanoparticles-film may be doped with at least one of Li, Mg, Al, Ti, Ga, and Zr. A TiO₂ film or a ZrO₂ film may be formed instead of the ZnO-nanoparticles film. A TFB film or a PVK film may be formed instead of the poly-TPD film.

The NiO_{y} layer of the light-emitting element (containing 0% of Cu) contains no non-nickel metal element (i.e., x=0).

Production of Light-Emitting Element (containing 15% of Cu) The production of the light-emitting element (containing 15% of Cu) is the same as the production of the light-emitting element (containing 0% of Cu) with the exception that a precursor solution (containing 15% of Cu) is used instead of the precursor solution (containing 0% of Cu).

The CuₓNi₍₁₋ₓ₎O_{y} layer of the light-emitting element (containing 15% of Cu) contains a non-nickel metal element, and x is equal to 0.15.

### Production of Light-Emitting Element (Containing 30% of Cu)

The production of the light-emitting element (containing 30% of Cu) is the same as the production of the light-emitting element (containing 0% of Cu) with the exception that a precursor solution (containing 30% of Cu) is used instead of the precursor solution (containing 0% of Cu).

The CuₓNi₍₁₋ₓ₎O_{y} layer of the light-emitting element (containing 30% of Cu) contains a non-nickel metal element, and x is equal to 0.3.

### Comparison Results

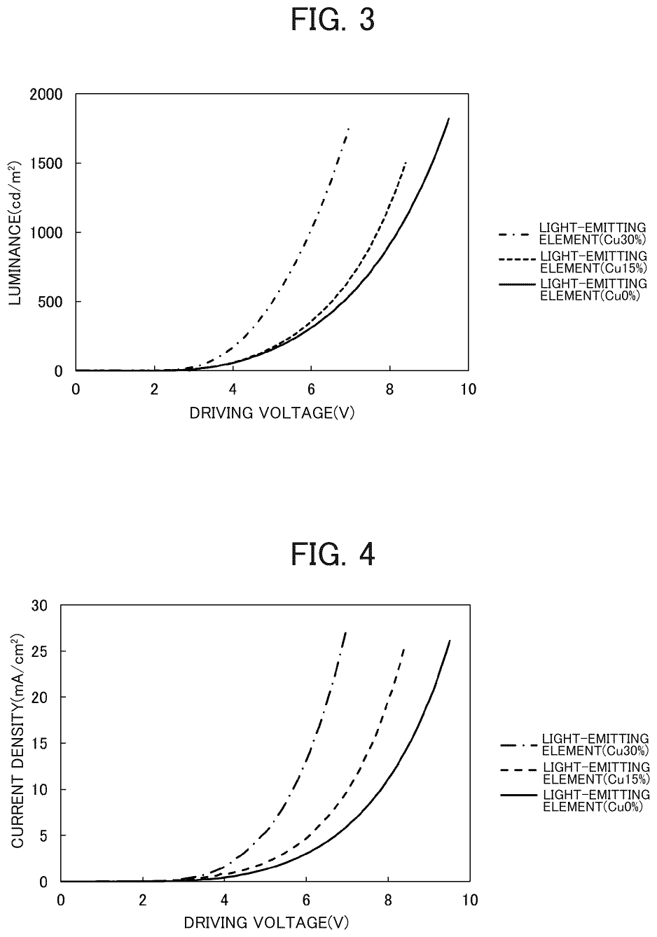

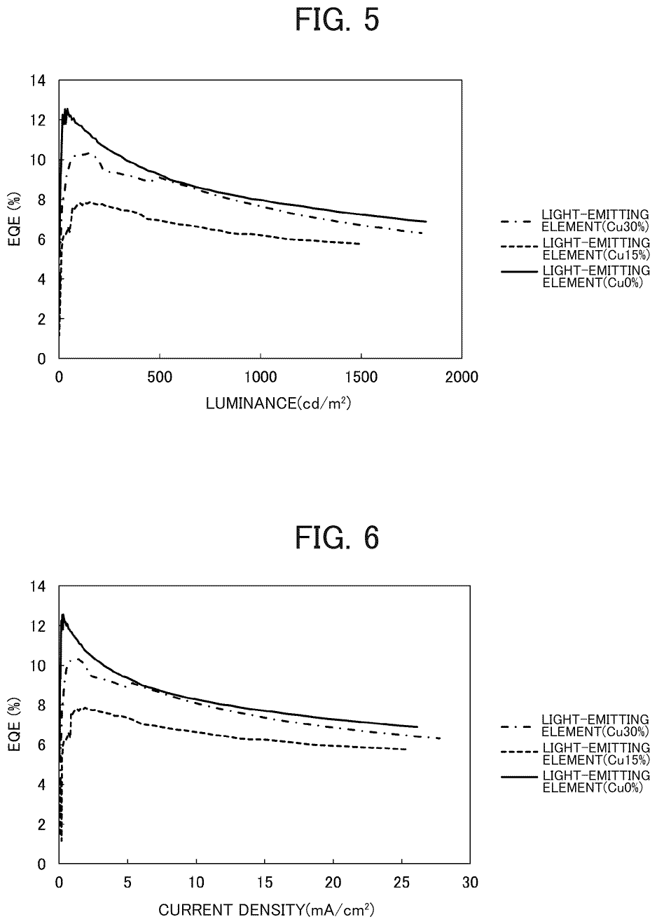

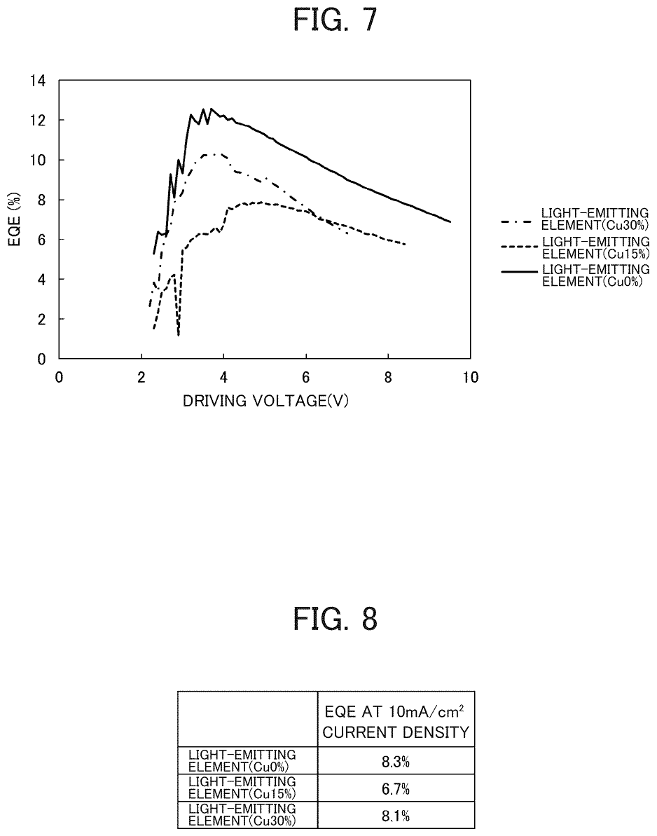

FIG. 3 is graphs showing the relationship of luminance (vertical axis) versus driving voltage (horizontal axis) in the light-emitting element (containing 0% of Cu), the light-emitting element (containing 15% of Cu), and the light-emitting element (containing 30% of Cu). FIG. 4 is graphs showing the relationship of current density (vertical axis) versus driving voltage (horizontal axis) in the light-emitting element (containing 0% of Cu), the light-emitting element (containing 15% of Cu), and the light-emitting element (containing 30% of Cu). FIG. 5 is graphs showing the relationship of EQE (vertical axis) versus luminance (horizontal axis) in the light-emitting element (containing 0% of Cu), the light-emitting element (containing 15% of Cu), and the light-emitting element (containing 30% of Cu). FIG. 6 is graphs showing the relationship of EQE (vertical axis) versus current density (horizontal axis) in the light-emitting element (containing 0% of Cu), the light-emitting element (containing 15% of Cu), and the light-emitting element (containing 30% of Cu). FIG. 7 is graphs showing the relationship of EQE (vertical axis) versus driving voltage (horizontal axis) in the light-emitting element (containing 0% of Cu), the light-emitting element (containing 15% of Cu), and the light-emitting element (containing 30% of Cu). FIG. 8 is a table showing EQE at a current density of 10 mA/cm² in the light-emitting element (containing 0% of Cu), the light-emitting element (containing 15% of Cu), and the light-emitting element (containing 30% of Cu).

FIG. 3 reveals that at the same luminance, the driving voltage in the light-emitting element (containing 15% of Cu) is lower than that in the light-emitting element (containing 0% of Cu), and the driving voltage in the light-emitting element (containing 30% of Cu) is lower than that in the light-emitting element (containing 15% of Cu).

FIG. 4 reveals that at the same driving voltage, the current density in the light-emitting element (containing 15% of Cu) is higher than that in the light-emitting element (containing 0% of Cu), and the current density in the light-emitting element (containing 30% of Cu) is higher than that in the light-emitting element (containing 15% of Cu). The driving voltage at a current density of 10 mA/cm² stands at 7.8 V in the light-emitting element (containing 0% of Cu), at 7.0 V in the light-emitting element (containing 15% of Cu), and at 5.7 V in the light-emitting element (containing 30% of Cu).

In FIG. 7, the EQE at a driving voltage of 6 V stands at 10.1% in the light-emitting element (containing 0% of Cu), at 7.4% in the light-emitting element (containing 15% of Cu), and at 7.6% in the light-emitting element (containing 30% of Cu).

FIG. 8 reveals that the light-emitting element (containing 0% of Cu), the light-emitting element (containing 15% of Cu), and the light-emitting element (containing 30% of Cu) all have high EQE, i.e., 6.7% or more. FIG. 8 reveals that the light-emitting element (containing 15% of Cu) has 6.7% EQE, which is sufficiently high, but this EQE is slightly lower than that of the light-emitting element (containing 0% of Cu). A possible reason is that since the CuₓNi₍₁₋ₓ₎O_{y} layer of the light-emitting element (containing 15% of Cu) contains Cu with x=0.15, its light transmittance is slightly reduced when compared with that of the CuₓNi₍₁₋ₓ₎O_{y} layer of the light-emitting element containing Cu in x=0. On the other hand, FIG. 8 reveals that the light-emitting element (containing 30% of Cu) has further improved EQE than the light-emitting element (containing 15% of Cu). A possible reason is that since the CuₓNi₍₁₋ₓ₎O_{y} layer of the light-emitting element (containing 30% of Cu) contains Cu in x=0.3, its light transmittance is slightly reduced when compared with that of the CuₓNi₍₁₋ₓ₎O_{y} layer of the light-emitting element containing Cu in x=0, but its carrier balance improvement thanks to hole injection improvement excels this reduction. That is, in x=0.15, the driving voltage remarkably reduces at sufficiently high EQE (with slight EQE reduction). In x=0.3, the driving voltage further remarkably reduces, and at the same time, EQE improves thanks to the carrier balance improvement.

### Light Transmittance of Metal Oxide Layer 2

A metal oxide film (containing 5% of Cu) corresponding to the metal oxide layer 2, a metal oxide film (containing 30% of Cu) corresponding to the metal oxide layer 2, and a metal oxide film (containing 50% of Cu) corresponding to the metal oxide layer 2 were formed, and their light transmittances were compared.

Here, 0.95 mmol of nickel acetate tetrahydrate (Ni(CH₃COOH)₂·4H₂O), 0.05 mmol of copper acetate monohydrate (Cu(CH₃COOH)₂·H₂O), and 5 mL of ethanol were put into a vial container and were stirred well for 30 minutes to prepare a precursor solution (containing 5% of Cu).

In addition, 0.5 mmol of nickel acetate tetrahydrate (Ni(CH₃COOH)₂·4H₂O), 0.5 mmol of copper acetate monohydrate (Cu(CH₃COOH)₂·H₂O), and 5 mL of ethanol were put into a vial container and were stirred well for 30 minutes to prepare a precursor solution (containing 50% of Cu).

### Formation of Metal Oxide Film (Containing 5% of Cu)

The precursor solution (containing 5% of Cu) underwent spin-coating application to a glass substrate under the atmosphere, followed by firing at 275 degrees for 1 hour to form a 45-nm thick metal oxide film (containing 5% of Cu). This corresponds to the second step. The metal oxide film (containing 5% of Cu) contains a non-nickel metal element, and x is equal to 0.05.

### Formation of Metal Oxide Film (Containing 30% of Cu)

The formation of the metal oxide film (containing 30% of Cu) is the same as the formation of the metal oxide film (containing 5% of Cu) with the exception that a precursor solution (containing 30% of Cu) is used instead of the precursor solution (containing 5% of Cu). The metal oxide film (containing 30% of Cu) contains a non-nickel metal element, and x is equal to 0.3.

### Formation of Metal Oxide Film (Containing 50% of Cu)

The formation of the metal oxide film (containing 50% of Cu) is the same as the formation of the metal oxide film (containing 5% of Cu) with the exception that a precursor solution (containing 50% of Cu) is used instead of the precursor solution (containing 5% of Cu). The metal oxide film (containing 50% of Cu) contains a non-nickel metal element, and x is equal to 0.5.

### Comparison Results

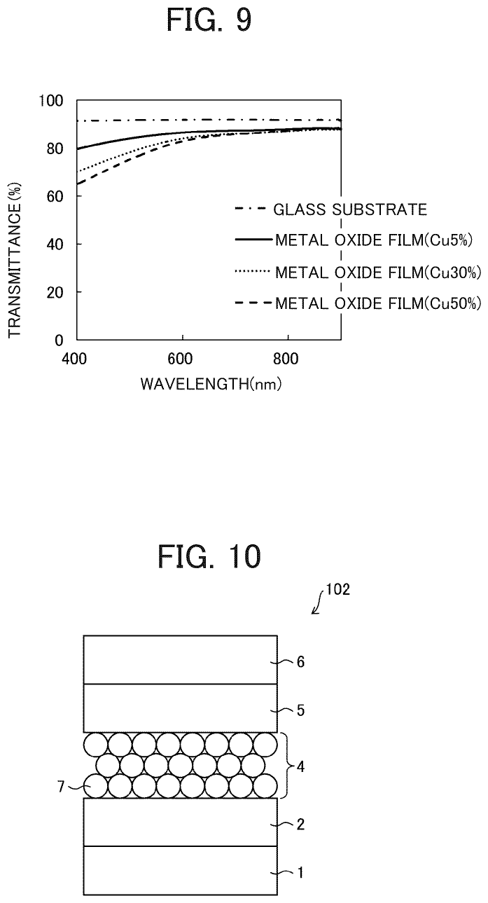

FIG. 9 is graphs showing the relationship of light transmittance (vertical axis) versus light wavelength (lateral axis) in the glass substrate, the metal oxide film (containing 5% of Cu), the metal oxide film (containing 30% of Cu), and the metal oxide film (containing 50% of Cu).

In the metal oxide film (containing 5% of Cu), the metal oxide film (containing 30% of Cu), and the metal oxide film (containing 50% of Cu), the larger the value x is, the smaller the light transmittance is; the light transmittance of the metal oxide film (containing 50% of Cu) with the largest x is slightly reduced with respect to the metal oxide film (containing 5% of Cu) with the smallest x. All the metal oxide film (containing 5% of Cu), the metal oxide film (containing 30% of Cu), and the metal oxide film (containing 50% of Cu) have a high light transmittance, i.e., 65% or more, in the whole of a visible-light range of 400 to 800 nm inclusive. This high light transmittance is achieved for the following two reasons.

The first reason is that the temperature of firing the precursor solution (containing 5% of Cu), precursor solution (containing 30% of Cu), and precursor solution (containing 50% of Cu) is low, i.e., 275 degrees, and the metal oxide film (containing 5% of Cu), metal oxide film (containing 30% of Cu), and metal oxide film (containing 50% of Cu) are polycrystalline or amorphous films with low crystallinity. It is conceivable that the low crystallinity results in low carrier activation ratio, thereby reducing light absorption performed by free carriers.

The second reason is that oxygen is less likely to enter crystals at a low temperature of firing than at a high temperature of firing, thereby reducing metal-element deficiencies, thus reducing hole concentration.

As described above, a polycrystalline or amorphous film with low crystallinity can prevent reduction in light transmittance even when doped with a large volume of a non-nickel metal element. A high light transmittance in visible light is preferable for enhancing the light extraction efficiency of the light-emitting element 101.

The configuration of the light-emitting element 101 is not limited to a conventional structure; a so-called inverted structure may be applied. In the light-emitting element 101 having an inverted structure includes the following stacked on the substrate (not shown in FIG. 1) in the stated order: the cathode 6, the electron transport layer 5, the quantum-dots layer 4, the organic carrier transport layer 3, the metal oxide layer 2, and the anode 1.

### Second Embodiment

FIG. 10 is a cross-sectional view of the schematic configuration of a light-emitting element 102 according to a second embodiment of the present disclosure. The light-emitting element 102 corresponds to the light-emitting element 101 with the organic carrier transport layer 3 omitted (when the light-emitting element 101 includes a self-assembled monolayer, this self-assembled monolayer is also omitted). It is noted that the light-emitting element 102 may include a self-assembled monolayer. In the light-emitting element 102 having this configuration, the quantum-dots layer 4 and the metal oxide layer 2 are in contact. In the light-emitting element 102, the metal oxide layer 2 functions as a hole injection-and-transport layer.

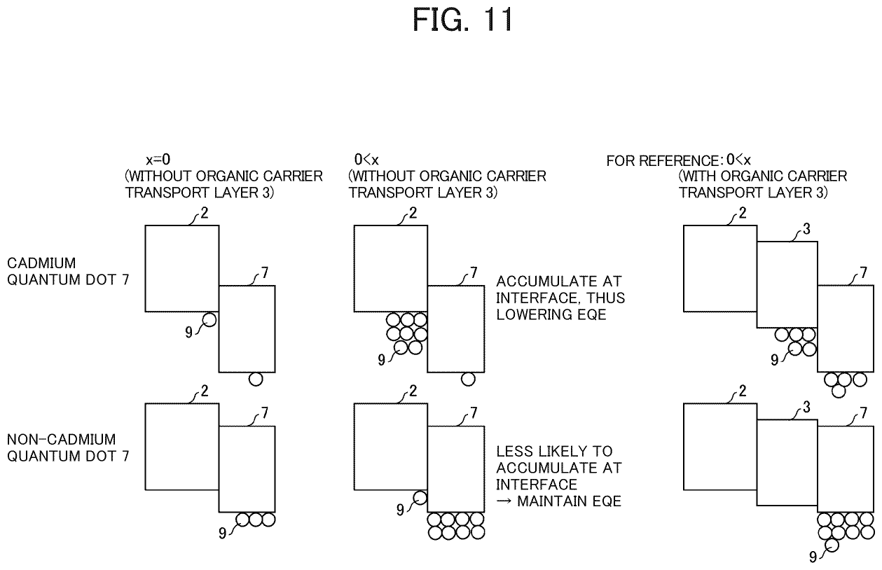

FIG. 11 illustrates injection of holes 9 from the metal oxide layer 2 into the quantum dot 7. For the quantum dot 7 that is a non-cadmium quantum dot, raising the conductivity of the metal oxide layer 2 sufficiently increases the amount of injection of the holes 9 into the quantum dot 7 without accumulating holes at the interface between the metal oxide layer 2 and quantum-dots layer 4 even when the organic carrier transport layer 3 is not provided, and even when the quantum-dots layer 4 and the metal oxide layer 2 are in contact. This can achieve the light-emitting element 102 with a low driving voltage and high EQE. This also improves hole injection in a QLED element, which exhibits electron excess, thus improving carrier balance, thus enhancing EQE.

Let the energy level of the highest occupied molecular orbital of the metal oxide layer 2 be denoted as HOMO (NiO), let the energy level of the highest occupied molecular orbital of the quantum dot 7 be denoted as HOMO (QD), and let the Fermi level of the anode 1 be denoted as HOMO (Anode). At this time, at least one of the following two mathematical expressions may be satisfied.

$$\begin{matrix}HOMO ( NiO ) - HOMO ( QD ) \leq 0.4 eV \\ HOMO ( Anode ) - HOMO ( NiO ) \leq 0.7 eV\end{matrix}$$

Satisfying HOMO (NiO)-HOMO (QD)≤0.4 eV sufficiently reduces the hole injection barrier between the metal oxide layer 2 and quantum-dots layer 4, so that holes are less likely to accumulate at the interface between the metal oxide layer 2 and quantum-dots layer 4, thereby preventing nonradiative recombination. This satisfaction also improves carrier balance, so that EQE can be enhanced.

Satisfying HOMO (Anode)-HOMO (NiO)≤0.7 eV sufficiently reduces the hole injection barrier between the anode 1 and metal oxide layer 2, so that the metal oxide layer 2 can improve its hole transport ability without being hindered by the barrier, thereby achieving the light-emitting element 102 with a low driving voltage.

Further, the light-emitting element 102 does not include an organic carrier transport layer, and all layers can be made of inorganic materials. This is preferable in terms of the reliability of the light-emitting element.

### Third Embodiment

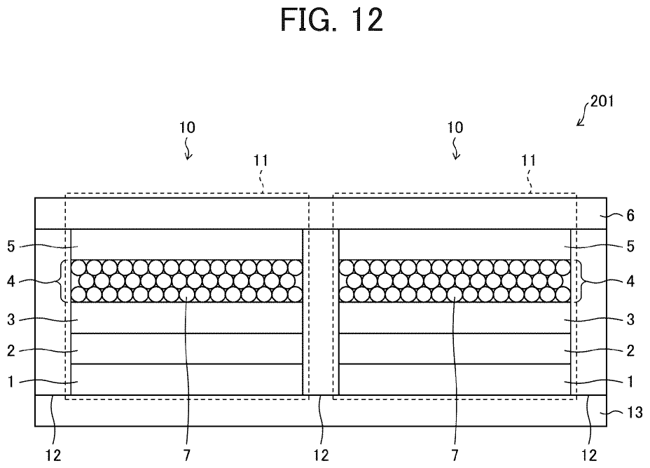

FIG. 12 is a cross-sectional view of the schematic configuration of a display device 201 according to a third embodiment of the present disclosure. The display device 201 is a QLED display device and includes a plurality of subpixels 10. Each of the plurality of subpixels 10 includes a light-emitting element 11. The light-emitting element 11 is the light-emitting element 101 or 102.

The display device 201 includes a partition wall 12. The partition wall 12 is positioned between the subpixels 10 adjacent to each other. The partition wall 12 contains at least one of polyimide resin, acrylic resin, polystyrene resin, and polyethylene resin.

The partition wall 12 is sensitive to heat. Accordingly, in the manufacture of the light-emitting element 11, the firing temperature for forming the metal oxide layer 2 is set at about 300 degree or less; this temperature setting is suitable for forming the metal oxide layer 2 containing nickel oxide with low crystallinity.

The display device 201 includes a flexible substrate 13. The flexible substrate 13 supports the light-emitting element 11 and the partition wall 12. The partition wall 13 contains at least one of polyimide, polystyrene, polyethylene, polyethylene naphthalate, and polyethylene terephthalate.

The flexible substrate 13 is sensitive to heat. Accordingly, in the manufacture of the light-emitting element 11, the firing temperature for forming the metal oxide layer 2 is set at about 300 degree or less; this temperature setting is suitable for forming the metal oxide layer 2 containing nickel oxide with low crystallinity.

### Additional Note

It can be interpreted that the inventor(s) of the present application has found the following.

Since doping the nickel oxide within the hole injection layer with 5 mol % or more of Cu reduces EQE considerably, they could not dope it with a large amount of Cu, so that the driving voltage of the light-emitting element was reduced insufficiently.

In this disclosure, they have discovered that the foregoing is attributed to the level of the quantum dots. That is, in a cadmium quantum dot, the energy barrier at the interface between the hole transport layer and quantum dot increases as its HOMO (VBM) becomes deep; raising the conductivity of the hole injection layer accumulates holes at the interface between the hole transport layer and quantum dot. This promotes nonradiative recombination of carriers and pushes down the EQE. On the other hand, using a non-cadmium quantum dot with a shallow level accumulates no holes at the interface between the hole transport layer and quantum dot even when the conductivity of the hole injection layer is raised. Accordingly, a large amount of Cu doping by the use of a non-cadmium quantum dot can sufficiently reduce the driving voltage of the light-emitting element without lowering the EQE.

### SUMMARY

Alight-emitting element according to a first aspect of the present disclosure includes the following: an anode; a cathode; a quantum-dots layer positioned between the anode and the cathode, and including a quantum dot; and a metal oxide layer positioned between the anode and the quantum-dots layer, and containing a nickel element and at least one non-nickel metal element selected from Li, Na, K, Rb, Cs, Fe, Co, Cu, and Ag at a composition ratio of (1-x):x, where 0.05≤x≤0.5 is satisfied.

The light-emitting element according to a second aspect of the present disclosure is configured, in the first aspect, such that the quantum dot is a non-cadmium quantum dot.

The light-emitting element according to a third aspect of the present disclosure is configured, in the first or second aspect, such that at least a part of the metal oxide layer has a structure of an amorphous metal oxide.

The light-emitting element according to a fourth aspect of the present disclosure is configured, in any one of the first to third aspects, such that at least a part of the metal oxide layer has a structure of polycrystals, and the average crystal particle diameter of the polycrystals is less than 25 percent of the thickness of the metal oxide layer.

The light-emitting element according to a fifth aspect of the present disclosure is configured, in any one of the first to fourth aspects, such that in an X-ray diffraction pattern, the peak of a nickel oxide (200) is not observed or is one-tenth or less as small as the highest peak.

The light-emitting element according to a sixth aspect of the present disclosure is configured, in any one of the first to fifth aspects, such that the metal oxide layer has a light transmittance of 65% or more at a wavelength of 400 to 700 nm inclusive.

The light-emitting element according to a seventh aspect of the present disclosure is configured, in any one of the first to sixth aspects, such that the at least one non-nickel metal element is Cu.

The light-emitting element according to an eighth aspect of the present disclosure is configured, in any one of the first to seventh aspects, such that the metal oxide layer includes a plurality of metal oxide crystals, and such that the plurality of metal oxide crystals has an average particle diameter of 30 nm or less.

The light-emitting element according to a ninth aspect of the present disclosure is configured, in any one of the first to eighth aspects, such that 0.15≤x is satisfied.

The light-emitting element according to a tenth aspect of the present disclosure is configured, in the ninth aspect, such that 0.25≤x is satisfied.

The light-emitting element according to an eleventh aspect of the present disclosure is configured, in any one of the first to tenth aspects, such that the quantum-dots layer is positioned higher than the metal oxide layer.

The light-emitting element according to a twelfth aspect of the present disclosure is configured, in any one of the first to eleventh aspects, such that the quantum dot contains at least one of Si, Ge, SiGe, AlSb, GaP, GaAs, GaSb, InP, InAs, InSb, ZnSiAs₂, ZnSiSb₂, ZnGeP₂, ZnGeAs₂, ZnGeSb₂, ZnSnP₂, ZnSnAs₂, ZnSnSb₂, CuGaS₂, CuGaSe₂, CuGaTe₂, CuInS₂, CuInSe₂, CuInTe₂, AgAlS₂, AgAlSe₂, AgAlTe₂, AgGaS₂, AgGaSe₂, AgGaTe₂, AgInS₂, AgInSe₂, and AgInTe₂.

The light-emitting element according to a thirteenth aspect of the present disclosure is configured, in any one of the first to twelfth aspects, such that the difference between the energy level of the highest occupied molecular orbital of the quantum dot and a vacuum level is 6 eV or less.

The light-emitting element according to a fourteenth aspect of the present disclosure includes, in any one of the first to thirteenth aspects, an organic carrier transport layer positioned between the quantum-dots layer and the metal oxide layer.

The light-emitting element according to a fifteenth aspect of the present disclosure is configured, in the fourteenth aspect, such that the organic carrier transport layer contains at least one of poly-TPD, TFB, PVK, TAPC, TCTA, α-NPD, and TPD.

The light-emitting element according to a sixteenth aspect of the present disclosure is configured, in the fourteenth or fifteenth aspect, such that the difference between the energy level of the highest occupied molecular orbital and a vacuum level in the organic carrier transport is larger than the difference between the energy level of the highest occupied molecular orbital and the vacuum level in the metal oxide layer.

The light-emitting element according to a seventeenth aspect of the present disclosure is configured, in any one of the fourteenth to sixteenth aspects, such that the difference between the energy level of the highest occupied molecular orbital of the organic carrier transport layer and a vacuum level is 5.1 eV or more.

The light-emitting element according to an eighteenth aspect of the present disclosure is configured, in any one of the first to thirteenth aspects, such that the quantum-dots layer and the metal oxide layer are in contact.

The light-emitting element according to a nineteenth aspect of the present disclosure is configured, in the eighteenth aspect, such that HOMO (NiO)-HOMO (QD)≤0.4 eV is satisfied, where HOMO (NiO) denotes the energy level of the highest occupied molecular orbital of the metal oxide layer, and where HOMO (QD) denotes the energy level of the highest occupied molecular orbital of the quantum dot.

The light-emitting element according to a twentieth aspect of the present disclosure includes, in any one of the first to nineteenth aspects, an electron transport layer positioned between the quantum-dots layer and the metal oxide layer, wherein the conductivity of the metal oxide layer is larger than the conductivity of the electron transport layer.

The light-emitting element according to a twenty-first aspect of the present disclosure is configured, in any one of the first to twentieth aspects, such that the metal oxide layer is 3 nm or less in surface roughness Rz.

The light-emitting element according to a twenty-second aspect of the present disclosure is configured, in any one of the first to twenty-first aspects, such that the metal oxide layer is formed higher than the anode, and such that the anode contains indium tin oxide.

The light-emitting element according to a twenty-third aspect of the present disclosure is configured, in any one of the first to twenty-second aspects, such that the metal oxide layer contains no carbon element or contains a carbon element whose mole ratio to a metal element including the nickel element and the at least one non-nickel metal element is 0.3 or less.

The light-emitting element according to a twenty-fourth aspect of the present disclosure is configured, in any one of the first to twenty-third aspects, such that HOMO (Anode)-HOMO (NiO) 0.7 eV is satisfied, where HOMO (NiO) denotes the energy level of the highest occupied molecular orbital of the metal oxide layer, and where HOMO (Anode) denotes the Fermi level of the anode.

A display device according to a twenty-fifth aspect of the present disclosure includes a plurality of subpixels each including the light-emitting element according to any one of the first to twenty-fourth aspects.

The display device according to a twenty-sixth aspect of the present disclosure includes, in the twenty-fifth aspect, a partition wall positioned between the plurality of subpixels adjacent to each other, and containing at least one of polyimide resin, acrylic resin, polystyrene resin, and polyethylene resin.

The display device according to a twenty-seventh aspect of the present disclosure includes, in the twenty-fifth or twenty-sixth aspect, a flexible substrate containing at least one of polyimide, polystyrene, polyethylene, polyethylene naphthalate, and polyethylene terephthalate.

A method for manufacturing a light-emitting element according to a twenty-eighth aspect of the present disclosure includes the following steps: forming an anode; firing, at 350 degrees or less, a coating film including a liquid containing c×(1−a) mol of a nickel element, and a liquid containing c×a mol of at least one non-nickel metal element selected from Li, Na, K, Rb, Cs, Fe, Co, Cu, and Ag, where a and c denote positive numbers, and where 0.05≤a≤0.5 is satisfied; forming a quantum-dots layer including a non-cadmium quantum dot; and forming a cathode.

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure. Furthermore, combining the technical means disclosed in the respective embodiments can form a new technical feature.

1. A light-emitting element comprising:
an anode;
a cathode;
a quantum-dots layer positioned between the anode and the cathode, and including a quantum dot; and
a metal oxide layer positioned between the anode and the quantum-dots layer, and containing a nickel element and at least one non-nickel metal element selected from Li, Na, K, Rb, Cs, Fe, Co, Cu, and Ag at a composition ratio of (1-x):x, where 0.05≤x≤0.5 is satisfied.

2. (canceled)

3. The light-emitting element according to claim 1, wherein at least a part of the metal oxide layer has a structure of an amorphous metal oxide.

4. The light-emitting element according to claim 1, wherein
at least a part of the metal oxide layer has a structure of polycrystals, and
an average crystal particle diameter of the polycrystals is less than 25 percent of a thickness of the metal oxide layer.

5. The light-emitting element according to claim 1, wherein in an X-ray diffraction pattern, a peak of a nickel oxide (200) is not observed or is one-tenth or less as small as a highest peak.

6. The light-emitting element according to claim 1, wherein the metal oxide layer has a light transmittance of 65% or more at a wavelength of 400 to 700 nm inclusive.

7. The light-emitting element according to claim 1, wherein the at least one non-nickel metal element is Cu.

8. The light-emitting element according to claim 1, wherein
the metal oxide layer includes a plurality of metal oxide crystals, and
the plurality of metal oxide crystals has an average particle diameter of 30 nm or less.

9. The light-emitting element according to claim 1, wherein 0.15≤x is satisfied.

10. (canceled)

11. The light-emitting element according to claim 1, wherein the quantum-dots layer is positioned higher than the metal oxide layer.

12. The light-emitting element according to claim 1, wherein the quantum dot contains at least one of Si, Ge, SiGe, AlSb, GaP, GaAs, GaSb, InP, InAs, InSb, ZnSiAs₂, ZnSiSb₂, ZnGeP₂, ZnGeAs₂, ZnGeSb₂, ZnSnP₂, ZnSnAs₂, ZnSnSb₂, CuGaS₂, CuGaSe₂, CuGaTe₂, CuInS₂, CuInSe₂, CuInTe₂, AgAlS₂, AgAlSe₂, AgAlTe₂, AgGaS₂, AgGaSe₂, AgGaTe₂, AgInS₂, AgInSe₂, and AgInTe₂.

13. The light-emitting element according to claim 1, wherein a difference between an energy level of a highest occupied molecular orbital of the quantum dot and a vacuum level is 6 eV or less.

14. The light-emitting element according to claim 1, comprising an organic carrier transport layer positioned between the quantum-dots layer and the metal oxide layer.

15. (canceled)

16. The light-emitting element according to claim 14, wherein a difference between an energy level of a highest occupied molecular orbital of the organic carrier transport layer and a vacuum level is larger than a difference between an energy level of a highest occupied molecular orbital of the metal oxide layer and a vacuum level.

17. The light-emitting element according to claim 14, wherein a difference between an energy level of a highest occupied molecular orbital of the organic carrier transport layer and a vacuum level is 5.1 eV or more.

18. The light-emitting element according to claim 1, wherein the quantum-dots layer and the metal oxide layer are in contact.

19. The light-emitting element according to claim 18, wherein HOMO (NiO)-HOMO (QD)≤0.4 eV is satisfied, where HOMO (NiO) denotes an energy level of a highest occupied molecular orbital of the metal oxide layer, and where HOMO (QD) denotes an energy level of a highest occupied molecular orbital of the quantum dot.

20-22. (canceled)

23. The light-emitting element according to claim 1, wherein the metal oxide layer contains no carbon element or contains a carbon element whose mole ratio to a metal element including the nickel element and the at least one non-nickel metal element is 0.3 or less.

24. The light-emitting element according to claim 1, wherein HOMO (Anode)-HOMO (NiO)≤0.7 eV is satisfied, where HOMO (NiO) denotes an energy level of a highest occupied molecular orbital of the metal oxide layer, and where HOMO (Anode) denotes a Fermi level of the anode.

25. A display device comprising a plurality of subpixels each including the light-emitting element according to claim 1.

26. (canceled)

27. The display device according to claim 25, comprising a flexible substrate containing at least one of polyimide, polystyrene, polyethylene, polyethylene naphthalate, and polyethylene terephthalate.

28. (canceled)
